(19) United States
(12) Patent Application Publication
(10) Pub. No.: US 2025/0034037 A1
(43) Pub. Date: Jan. 30, 2025

(54) SUBSTRATE WITH HARD ANTIREFLECTIVE COATING

(71) Applicant: Schott AG, Mainz (DE)

(72) Inventors: Christian Henn, Mainz (DE); Ashish Lepcha, Mainz (DE); Andreas Hahn, Mainz (DE)

(73) Assignee: Schott AG, Mainz (DE)

(21) Appl. No.: 18/785,198

(22) Filed: Jul. 26, 2024

(30) Foreign Application Priority Data
Jul. 26, 2023 (DE) 10 2023 119 824.6

(51) Int. Cl. C03C 17/34; C23C 14/06; C23C 14/10; C23C 14/34; G02B 1/115

(52) U.S. Cl. CPC C03C 17/3435; C23C 14/0652; C23C 14/10; C23C 14/3464; G02B 1/115; C03C 2217/734; C03C 2218/154

(57) ABSTRACT

A coated substrate includes a substrate and a multilayered antireflective coating built up from layers having different refractive indices on at least one side of the substrate. Layers having a relatively high refractive index and layers having a relatively low refractive index alternate and at least one layer having a relatively low refractive index is composed of a composition X containing silicon oxide and zirconium oxide. A proportion of zirconium in a metallic and semiconducting component in the composition X is 0.2% to 10% by weight.

### CROSS REFERENCE TO RELATED APPLICATIONS

This application claims priority to German Patent Application No. 10 2023 119 824.6 filed on Jul. 26, 2023, which is incorporated in its entirety herein by reference.

### BACKGROUND OF THE INVENTION

### 1. Field of the Invention

The present invention relates to an antireflective-coated, optionally transparent substrate, to a process for producing the coated substrate and to the use thereof. The invention especially relates to coated substrates coated with antireflective coatings with high resistance to scratching or other wear.

### 2. Description of the Related Art

Interference optical coatings are today often used as an antireflective coating, i.e. as antireflective or AR coatings, to improve the transmittance of transparent substrates, for instance of viewing window or filters, or otherwise attenuate disruptive reflections at the substrate. Depending on the intended use of the substrate, the antireflective coating can succumb to high wear stresses. However, scratches and other damage result in haze due to light scattering and, through alteration of the coating, reduce its antireflective effect and therefore act precisely contrary to the purpose of an antireflective coating.

The uppermost layer of the layer stack of the antireflective coating is formed from a low refractive index layer, generally from a silicon oxide layer SiO₂. The disadvantage here is that the low refractive index silicon oxide layer is very soft compared to the customary high refractive index materials. Precisely the uppermost layer can therefore suffer rapid wear. If the uppermost layer has been worn away, a high refractive index layer forms the surface. This leads to a reversal of the antireflective effect and the layer now functions more like a dielectric mirror.

There is therefore a need for an antireflective coating having a high resistance to scratching and abrasion. EP 2 492 251 B1 describes the production of antireflective coating systems for, inter alia, the watch glass industry. In addition to the antireflective effect, the hardness of the AR system is here improved by introducing a hard material layer of Si₃N₄ with an addition of aluminum as a high refractive index layer. Since watches and especially so-called magnifiers for the date display, which are glued to the watch glass, are often subjected to mechanical stress by scratching, the use of conventional antireflective coating systems is not advantageous, since the mechanical stress can completely remove these, thus leading to reflection of the substrate material. The hard AR system based on the development according to EP 2 492 251 B1 provides an antireflective system which is mechanically much more resistant than conventional optical coatings.

DE 10 2016 125 689 A1 and DE 10 2014 104 798 A1 describe AR systems having a modified composition of the high refractive index layer, wherein the layers according to DE 10 2016 125 689 A1 are amorphous while the layers according to DE 10 2014 104 798 A1 contain nano-crystallites.

The aforementioned prior art describes layer systems consisting of hard, high refractive index layers and low refractive index SiO₂. Since due to the antireflective system the SiO₂ must in any case form the terminating layer but SiO₂ is not a hard material layer, the last layer always forms the weak point of the system towards the abrasive medium.

### SUMMARY OF THE INVENTION

The invention has been developed in the hopes of further improving the abrasion resistance of antireflective layers, in particular to provide an antireflective layer whose terminating layer exhibits an elevated scratch resistance compared to the hitherto employed terminating layers of SiO₂ while simultaneously exhibiting only a small change, if any, in the refractive index in the visible spectral range and also to provide a layer system which reduces the reflectance of the substrate.

A first aspect provided according to the invention relates to a coated substrate which comprises on at least one side a multilayered antireflective coating built up from layers having different refractive indices, wherein layers having a relatively high refractive index and layers having a relatively low refractive index alternate and wherein at least one layer having a relatively low refractive index is composed of a composition X containing silicon oxide and zirconium oxide, wherein the proportion of zirconium in the metallic and semiconducting component in the composition X is 0.2% to 10% by weight, optionally 0.2% to 5% by weight, optionally 0.5% to 3% by weight.

In some embodiments according to the invention, a process for producing a coated substrate includes applying a multilayered antireflective coating on at least one side of a substrate. The antireflective coating is built up from layers having different refractive indices by successive deposition. Layers having a relatively high refractive index and layers having a relatively low refractive index alternate. The layers having a relatively low refractive index are built up from silicon oxide including a proportion of aluminum and wherein at least one layer having a relatively low refractive index which is composed of a composition X containing silicon oxide and zirconium oxide is applied. A proportion of zirconium in a metallic and semiconducting component in the composition X is 0.2% to 10% by weight.

In some embodiments according to the invention, a component includes a coated substrate including a substrate and a multilayered antireflective coating built up from layers having different refractive indices on at least one side of the substrate. Layers having a relatively high refractive index and layers having a relatively low refractive index alternate and at least one layer having a relatively low refractive index is composed of a composition X containing silicon oxide and zirconium oxide. A proportion of zirconium in a metallic and semiconducting component in the composition X is 0.2% to 10% by weight. The component is selected from the group consisting of: a watch glass; an optical component; a head-up display; an eyepiece for augmented reality; a cooking surface; a display for smartwatches, tablet PCs, or mobile telephones; and a touch display for smartwatches, tablet PCs, or mobile telephones.

These and other aspects and objects, features and advantages of the present invention will become apparent upon a consideration of the following detailed description and the invention when read in conjunction with the drawing figures.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIGS. 1A, 1B, 1C, and 1D illustrate a schematic section through embodiments with AR-coated substrates;

FIG. 2 illustrates the improvement in mechanical properties of three substrates coated according to the invention (examples 1, 2 and 3) relative to the SiO₂ reference (comp. ex. 1);

FIGS. 3A, 3B, and 3C show wear images recorded with an optical microscope of the coated substrates of example 2 (FIG. 3B), an SiO₂ reference (comp. ex. 1, FIG. 3A) and comp. ex. 2 (FIG. 3C), only slight superficial damage on the layer is apparent in FIG. 3B but the SiO₂ reference sample in FIG. 3A shows clear damage and layer removal;

FIGS. 4A and 4B show detail views of scratch tests for the SiO₂ reference (comp. ex. 1, FIG. 4B) and a Zr:SiOₓ coating provided according to the invention (ex. 2, FIG. 4A); and

FIG. 5 shows the profile of the refractive index of the AR coating from Example 2.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION OF THE INVENTION

It is to be understood that both the foregoing general description and the following detailed description are merely exemplary of the invention and are intended to provide an overview or framework for understanding the nature and character of the invention as claimed.

A layer having a relatively low refractive index, which is composed of a composition X containing silicon oxide and zirconium oxide and wherein the proportion of zirconium in the metallic and semiconducting component in the composition X is 0.2% to 10% by weight, optionally 0.2% to 5% by weight, optionally 0.5% to 3% by weight, is hereinbelow also referred to as a Zr:SiOₓ layer.

It is well known that pure ZrO₂ exhibits good mechanical resistance. However, the disadvantage of using ZrO₂ in coating solutions is that ZrO₂ has a very high refractive index of >2.2 and therefore cannot be used as a low refractive index layer in an AR coating. In the prior art this material is therefore only used as a high refractive index layer in optical layer systems.

It has surprisingly been found that adding only very little zirconium in the production process of a coating of SiO₂, for example in a sputtering process by co-sputtering of Si and Zr or via an SiZr alloy target, very markedly alters the mechanical properties of the produced coating while the optical properties of the coating remain virtually unchanged. Careful selection of the proportion of zirconium in the coating thus makes it possible to adjust the refractive index such that the Zr:SiOₓ layer may be used as a low refractive index layer and/or as a terminating layer in an AR system.

The refractive index of a Zr:SiOₓ layer becomes ever higher, the higher the selected proportion of zirconium in the coating. However, it has surprisingly been found that above a threshold value for the content of zirconium in the Zr:SiOₓ layer the mechanical resistance to scratches in the coating deteriorates again at further increasing zirconium content. This surprisingly makes it possible to produce a Zr:SiOₓ layer with optimum mechanical resistance coupled with a sufficiently low refractive index. This moreover shows a positive effect on the coating costs, since Zr is a relatively costly material and the sputtering rate of layers containing a large proportion of SiOₓ is higher than that of layers containing a large proportion of ZrOₓ.

The composition X of the layer having a relatively low refractive index may contain further components in addition to zirconium oxide and silicon oxide. If for example only silicon and zirconium are present as metallic and semiconducting components in the composition of the layer, the aforementioned proportion of zirconium in composition X is synonymous with the requirement:

$$0.2 \leq ( Zr / ( Zr + Si ) * 100 \leq 10 ,$$

$$optionally$$

$$0.2 \leq ( Zr / ( Zr + Si ) * 100 \leq 5 ,$$

$$optionally$$

$$0.5 \leq ( Zr / ( Zr + Si ) * 100 \leq 3 ,$$

wherein Zr is the content of zirconium in % by weight in the layer and wherein Si is the content of silicon in % by weight in the layer. If in some embodiments further metallic and semiconducting components are present in the composition X of the Zr:SiOₓ layer the denominator of the aforementioned relations would require a corresponding increase.

The Zr:SiOₓ layer may in principle contain not only silicon oxide and zirconium oxide but also further components, for example aluminum, boron, titanium, nickel, tin, gallium, yttrium, hafnium, chromium and/or oxides thereof and carbon. Especially in case of production of the Zr:SiOₓ layer by a sputtering process these may be incorporated into the Zr:SiOₓ layer specifically through doping in the target material or through impurities in the target material. However, it is optionally provided that the Zr:SiOₓ layer comprises at least 80% by weight, in particular at least 90% by weight, or even up to 95% by weight or 99% by weight of silicon oxide and zirconium oxide.

The layer thickness of a Zr:SiOₓ layer may be in the range from 10 to 300 nm, optionally between 10 and 200 nm, optionally between 50 and 150 nm.

### Antireflective Coating

The AR coating is designed as an interference optical coating with several dielectric layers. In the context of the present invention a dielectric layer is especially to be understood as meaning a low or high refractive index layer or a relatively low or relatively high refractive index layer which contributes to an antireflective effect of the AR coating. The layer system of the AR coating comprises alternating low refractive index and high refractive index layers.

In some embodiments the low refractive index layers have a refractive index in the range from 1.3 to 1.6, in particular in the range from 1.45 to 1.5, at a wavelength of 550 nm. This makes it possible to achieve a high antireflective effect.

In some embodiments the high refractive index layer has a refractive index in the range from 1.8 to 2.3, in particular in the range from 1.95 to 2.1, at a wavelength of 550 nm.

In some embodiments the high refractive index layers have layer thicknesses of 100 to 500 nm, optionally 100 to 300 nm, optionally 100 to 200 nm and in some embodiments the low refractive index layers have layer thicknesses of 60 to 200 nm, optionally 60 to 100 nm.

The uppermost dielectric layer/the terminating layer is a low refractive index layer. The uppermost layer is to be understood as meaning the layer having the greatest distance to the substrate.

Accordingly, the first/lowermost layer of the AR coating is the layer closest to the substrate and in some embodiments is arranged immediately atop the substrate. The refractive index of the lowermost layer depends on the refractive index of the substrate. If the substrate has a refractive index which is higher than the refractive index of the low refractive index layers of the AR coating, a low refractive index layer as the first layer of the AR coating may be advantageous. If the substrate has a refractive index which is the same as or lower than the refractive index of the low refractive index layer of the AR coating, a relatively high refractive index layer as the first layer of the AR coating is advantageous.

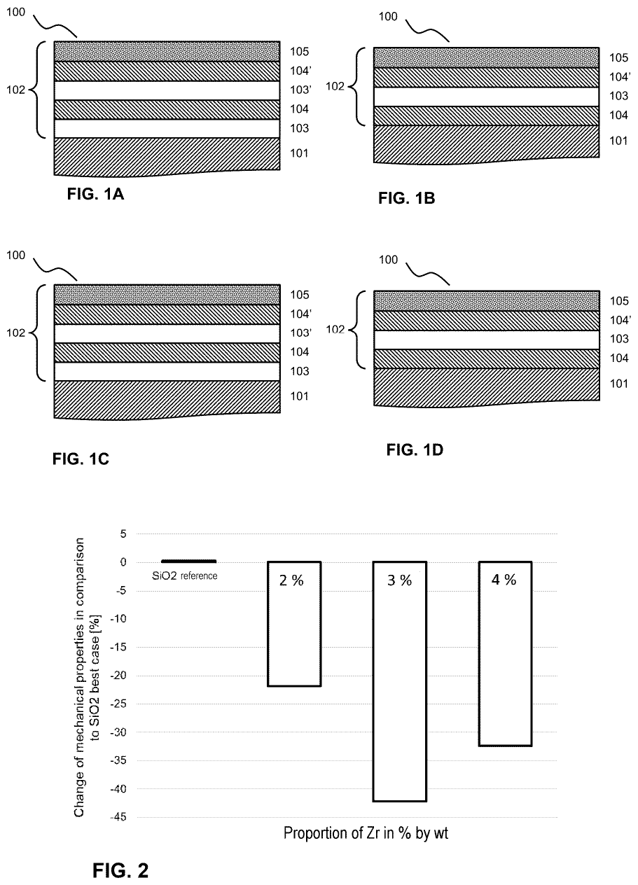

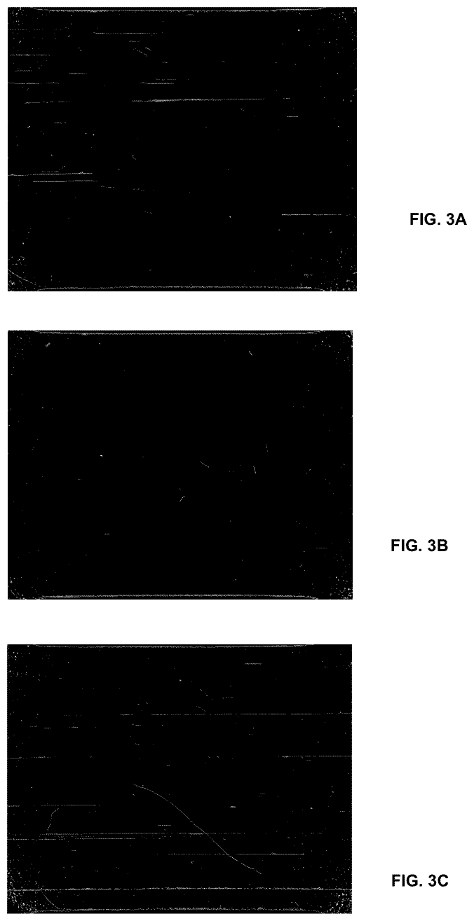

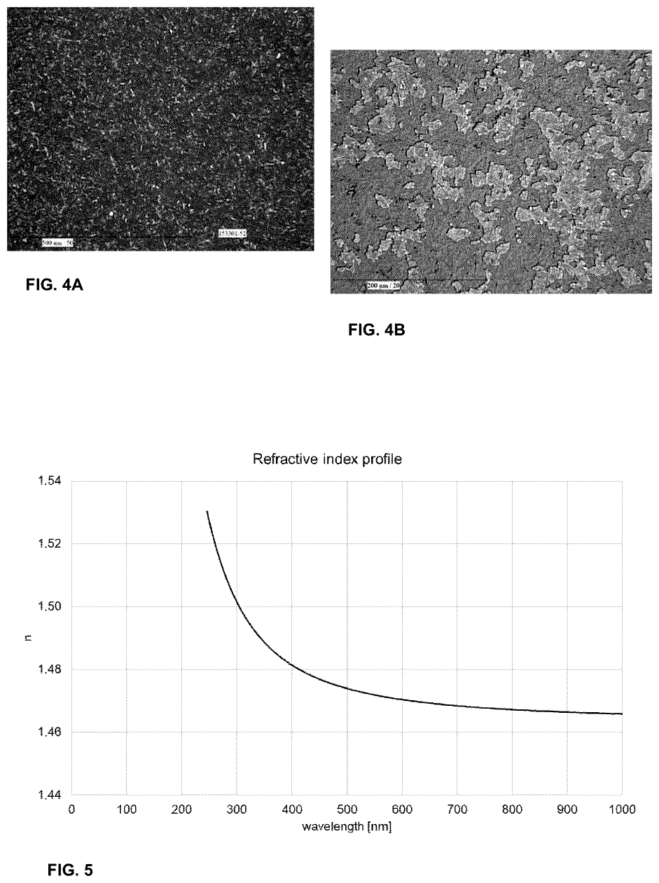

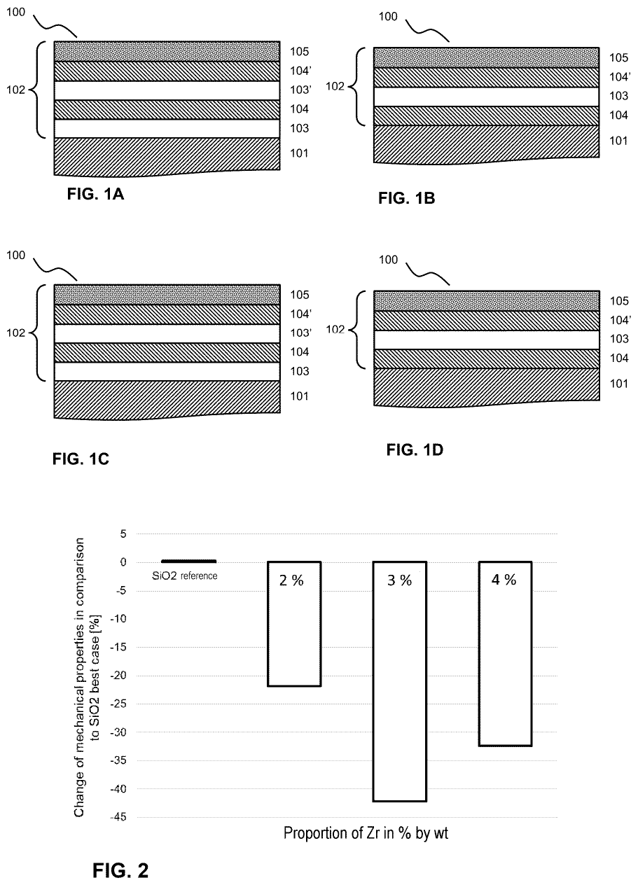

In the case of a substrate having a relatively low refractive index, the AR coating optionally comprises at least four layers, for example four or six layers, in order to achieve both a good scratch resistance effect and a good antireflective effect (FIG. 1B and FIG. 1D). It may thus be advantageous when the antireflective coating comprises at least two layers having a relatively high refractive index and at least two layers having a relatively low refractive index, wherein the coating employs a relatively high refractive index layer as the first layer and a low refractive index layer as the terminating layer (FIG. 1B).

By way of example, the individual layers may have the following layer thickness ranges: for the lowermost/first layer 5 to 40 nm, for the subsequent/second layer 10 to 40 nm, for the subsequent layer/third layer, which in this variant is the second layer from the top of the layer stack and thus forms the uppermost high refractive index layer of the layer stack, 100 to 200 nm, optionally more than 120 nm, and for the uppermost/fourth layer 40 to 120 nm, optionally 60 to 100 nm.

The layer design elucidated above as shown by way of example in FIG. 1B is particularly well-suited for glass and glass ceramic substrates.

In a substrate having a relatively high refractive index, the AR coating is formed from at least two low refractive index layers and at least one high refractive index layer. In this embodiment, the high refractive index layer is arranged between the two low refractive index layers. For a better antireflective effect, an AR coating on a substrate having a relatively high refractive index is optionally composed of at least five (FIG. 1A), seven (FIG. 1C) or nine layers. Additional layers may be added but the costs of the AR coating increase with further layers.

In a development of the invention, the substrate may have a curved surface, especially a lenticular surface, which is coated with an AR coating.

### Composition of Layers Having a Relatively Low Refractive Index

The AR coating contains at least two, but usually three or more low refractive index layers/layers having a relatively low refractive index. If two or more layers having a relatively low refractive index are present these layers may have the same composition or different compositions.

At least one layer having a relatively low refractive index is a Zr:SiOₓ layer and it may be preferable to employ a Zr:SiOₓ layer at least as the uppermost layer/terminating layer. However, Zr:SiOₓ may also be used for one or more further low refractive index layers or for all low refractive layers of the AR coating.

However, one or more low refractive index layers of different composition may also be present in addition to the at least one Zr:SiOₓ layer. In some embodiments such low refractive index layers are made of SiO₂ or doped SiO₂. The doped SiO₂ is in particular an SiO₂ doped with one or more oxides, nitrides, carbides and/or carbonitrides selected from the group of the elements aluminum, boron, titanium, chromium or carbon. Alternatively or in addition, the low refractive index layer may contain nitrogen.

In some embodiments the doped SiO₂ is an aluminum-doped SiO₂, i.e. SiAlOₓ having silicon contents in the range from 1% to 99% by weight, optionally in the range from 85% to 95% by weight.

The addition of aluminum or aluminum oxide provides the soft silicon oxide layers with a higher resistance to scratches and abrasion. The aluminum doping should optionally account for no more than 20 mol % of the silicon content. In other words it may be preferable when the ratio of the molar amounts of aluminum to silicon is at most 0.2. The following then applies for the molar amounts n(Si) and n(Al) of silicon and aluminum respectively:

$$n ( Al ) / ( n ( Si ) + n ( Al ) ) = x , where x is in the range from 0.05 to 0.2$$

If the aluminum content becomes excessive this ultimately results in a reduction in the antireflective effect on account of the increasing refractive index of the low refractive index layers.

### Composition of Layers Having a Relatively High Refractive Index

The AR coating contains at least one, but usually two or more high refractive index layers/layers having a relatively high refractive index. If two or more layers having a relatively high refractive index are present these layers may have the same composition or different compositions.

The high refractive index layers may contain an oxide, silicide, carbide or nitride or mixed forms thereof of one or more metallic and semiconducting components such as for example silicon, boron, zirconium, titanium, nickel, chromium, tin, hafnium, gallium and/or yttrium. Examples include Si₃N₄, SnO₂, AlN and AlN:SiN which may be doped with other metallic and/or semiconducting components.

In some embodiments the high refractive index layer may be silicon nitride Si₃N₄. In addition to silicon nitride the layer may contain at least one further constituent, for example one or more further nitrides, carbides and/or carbonitrides. It may be preferable when the nitrides, carbides or carbonitrides are the corresponding compounds of the elements silicon, boron, zircon, titanium, nickel, chromium and/or carbon. Corresponding mixed layers are also referred to as doped Si₃N₄ layers. The compounds present in addition to the Si₃N₄ are referred to as dopant, wherein the content of dopant may be up to 50% by weight. In the context of the present invention the term doped layers is also to be understood as encompassing layers containing a content of up to 50% by weight of dopant.

Another high refractive index layer that may be employed is a high refractive index hard material layer which may be a pure aluminum nitride layer. Alternatively, such a hard material layer may also contain further constituents, for example one or more further nitrides, carbides and/or carbonitrides, in addition to aluminum nitride. It may be preferable when the nitrides, carbides or carbonitrides are the corresponding compounds of the elements silicon, boron, zircon, titanium, nickel, chromium and/or carbon. Corresponding mixed layers are also referred to as doped AlN layers. The compounds present in addition to the AlN are referred to as dopant, wherein the content of dopant may be up to 50% by weight. In the context of the present invention the term doped layers is also to be understood as encompassing layers containing a content of up to 50% by weight of dopant.

In some embodiments such a high refractive index layer contains boron nitride in addition to aluminum nitride, i.e. the layer is doped with boron nitride. The boron nitride present reduces the coefficient of friction of the layer which especially results in a higher resistance of the layer to polishing processes. This is advantageous both in terms of the resistance of a correspondingly coated substrate during use by the end-user and in terms of possible process steps in the further processing of the coated substrate.

In a further embodiment high refractive index layers employed can further include silicon-doped aluminum nitride coatings (AlN:SiN), wherein the content of AlN is optionally 75% by weight and/or the content of SiN is optionally 25% by weight. This AlN:SiN material system makes it possible to influence individual properties such as adhesion, hardness, roughness, coefficient of friction and/or the thermal resistance of the AR coating.

In a further embodiment the high refractive index layer may be crystalline aluminum nitride having a hexagonal crystal structure with a predominating (001) preferred direction. The proportion of AlN in the hard material layer is optionally greater than 50% by weight. An AR coating which is particularly scratch resistant and resistant to wear and polishing stresses is obtainable when the AlN of the hard material layer is crystalline or at least largely crystalline and has a hexagonal crystal structure. The AlN layer especially has a degree of crystallization of at least 50%. To employ the high refractive index layer together with low refractive index layers in an interference optical system, a crystalline high refractive index layer must also exhibit sufficient transparency. A high transparency of a crystalline high refractive index layer is achievable especially through a small size of the individual crystallites in the layer. The small size avoids scattering effects for example. In some embodiments the average crystal size is not more than 20 nm, optionally not more than 15 nm, and optionally 5 to 15 nm. A further advantage of small crystal size is the higher mechanical resistance of the layer containing the crystallites. Larger crystallites often exhibit a displacement in their crystal structure which has an adverse effect on mechanical resistance. AlN crystallites in the hard material layer have a hexagonal crystal structure with a predominating preferred direction in the (001) direction, i.e. parallel to the substrate surface. In a crystal structure having a preferred direction one of the directions of symmetry of the crystal structure is optionally occupied by the crystallites. In the context of the present invention an AlN crystal structure having a preferred direction in the (001) direction is especially to be understood as meaning a crystal structure which in X-ray diffractometric measurement shows a maximum reflection in the corresponding XRD spectrum in the range between 34° and 37° (grazing incidence measurement: GIXRD). The reflection in this region may be assigned to an AlN crystal structure having a (001) preferred direction.

### Properties of the Coated Substrate According to the Invention

The coated substrate according to the invention has a good antireflective effect coupled with high mechanical resistance and wear resistance.

The high mechanical resistance is apparent for example in that the residual reflection at a wavelength of 750 nm after mechanical stress in the so-called Bayer test is altered by at most 35% based on the reflection of the uncoated substrate, optionally by at most 25%, or in that the residual reflection of the coated substrate at a wavelength of 750 nm after the Bayer test is less than 5%, optionally less than 3% and optionally less than 2.5%. By contrast, interference optical coatings such as are known from the prior art show a change of about 50% based on the uncoated substrate.

In the Bayer test a coated substrate having a diameter of 30 mm is laden with 90 g of sand and this is passed over the substrate in 13 500 oscillations over a period of about one hour.

Another measure of the high mechanical resistance of a substrate coated according to the invention is the haze of the AR coating after the Bayer test as determined according to ASTM D 1003, D1044. The coated substrate optionally exhibits a haze after the Bayer test which is at most 5% or even at most 3% higher than the haze of the coated substrate before the Bayer test.

The scratch resistance of an AR coating depends not only on the hardness but also on the quality of adhesion of the individual layers/partial layers to one another and the quality of adhesion of the AR coating to the substrate. If the individual layers of the AR coating and/or the substrate also show different coefficients of thermal expansion this can lead to the build-up of stresses in the AR coating and to flaking of the AR coating.

The resistance of a Zr:SiOₓ layer as the terminating layer, and thus also of the substrate coated according to the invention, to abrasion also depends on the ratio of hardness and elastic modulus of the respective layer. It is therefore preferable when the high refractive index layers have a ratio of hardness to elastic modulus of at least 0.08, optionally 0.1, optionally greater than 0.1. This is achievable by the (001) preferred direction. Layers comparable in terms of their composition having a different preferred direction show comparatively low values in the range from 0.06 to 0.08.

The AR coating according to the invention also has exceptional chemicals resistance.

The antireflective coating of the coated substrate may have a Martens hardness of 3.5 to 7 GPa. The Martens hardness may be determined for example by the Martens hardness test method according to DIN EN ISO 14577.

In a development of the invention it is provided that a Zr:SiOₓ layer has an elastic modulus (E modulus) of less than 150 GPa, optionally less than 100 GPa. The Zr:SiOₓ layer is therefore relatively deformable. Accordingly, avoidance of scratching by such a Zr:SiOₓ layer is not only based on a high hardness of the coating preventing penetration of particles into the Zr:SiOₓ layer through inelastic deformation and damage to the coating in certain areas. On the contrary, penetration of particles into the Zr:SiOₓ layer can be tolerated to a certain extent since a deformation of the coating caused thereby may be substantially elastic and is thus reversible and does not lead to formation of scratches.

A low coefficient of friction of a coating is usually directly related to a roughness of the surface of the coating. A low roughness of the surface is in turn advantageous for avoidance of scratches since the surface provides only a small target for forces acting parallel to the surface of the coating.

In a development of the invention the surface of the antireflective coating or of the first layer of the antireflective coating thus has a mean roughness and a root mean square roughness which is in each case less than 1.5 nm, optionally less than 1 nm, based on an area of one square micrometer.

Antireflective coatings with a reduction in reflectivity of more than 3% with a neutral color impression are achievable. The reflectivity in the visible spectral range is generally less than 1%.

### Substrate

Contemplated substrates include transparent inorganic materials, such as glasses and transparent and opaque glass ceramics, also sapphire glasses, synthetic optionally Ti-doped quartz glass (fused silica) or crystals for optical purposes for example, such as calcium fluoride. Optical glasses and filter glasses or plastics for optical purposes may also be used as substrates. Alternatively, the substrate may also be made of a borosilicate glass, aluminum silicate glass, soda-lime glass or lithium-aluminosilicate glass, wherein these may also be chemically or thermally toughened substrates.

Laminate/Composite materials, especially comprising glasses, as used in vehicle glazing for example are also suitable. The laminate may also be produced after coating with the antireflective coating. Such a laminate may be produced for example by bonding two glass panes to one another with a PVB film.

### Applications

The layer system of the antireflective coating according to the invention is advantageous wherever antireflective layer systems are subjected to mechanical stress. Possible applications include use in viewing windows in the vehicle sector, including aircraft, cooking surfaces or similar household appliances made of glass or glass ceramic, applications in the consumer electronics sector, such as covers of electronic displays and touch screens, and also for watch glasses which may have a flat or slightly curved surface. A curved watch glass may also include for example a lens adhering to or incorporated into the date display on the watch glass, for example with a diameter of 7 mm and an arrow height, i.e. the height of the lens from a notional plane surface at the edge of the curved area to the vertex of the curved area, of 0.4 mm. The antireflective coating according to the invention with long-lasting scratch resistance may likewise be applied in the case of such slightly curved watch glasses.

Also conceivable are AR coatings of oven viewing windows, control panels, worktops, protective screens in the automotive sector, consumer electronics, mobile phones, watches and smartwatches.

The invention thus also relates to a component or optical component comprising a coated substrate, wherein the component is optionally selected from components for the aforementioned application fields and is optionally selected from components from the group consisting of a watch glass, an optical component, a head-up display, an eyepiece for augmented reality, a cooking surface, a display for smartwatches, tablet PCs or mobile telephones or a touch display for smartwatches, tablet PCs or mobile telephones.

### Production Process

The invention further relates to a process for producing such a coated substrate
where on at least one side of the substrate a multilayered antireflective coating is applied,
which is built up from layers having different refractive indices by successive deposition, wherein layers having a relatively high refractive index and layers having a relatively low refractive index alternate,
wherein at least one layer having a relatively low refractive index which is composed of a composition X containing silicon oxide and zirconium oxide is applied, wherein the proportion of zirconium in the metallic and semiconducting component in the composition X is 0.2% to 10% by weight, optionally 0.2% to 5% by weight, optionally 0.5% to 3% by weight.

One or more layers of the AR coating may be produced by sputtering onto the surface of the substrate. Targets provided for sputtering generally comprise at least one metallic or semiconducting component. The targets employed may be composed of only one metallic or semiconducting component or else may be composite or alloy targets. Sputtering may moreover employ only a single target or two or more targets are employed in a so-called co-sputtering process.

A Zr:SiOₓ layer may also be applied to the surface of the substrate 101 by sputtering for example. This may accomplished for example through co-sputtering of silicon and zirconium with addition of oxygen as reactive gas to produce a Zr:SiOₓ layer. The proportion of Zr in the layer may be adjusted by adjusting the sputtering power. The higher the sputtering power, the greater the proportion of sputtered Zr and thus proportion of Zr in the sputtered layer. In this embodiment the sputtering power may be at least 0.2 kW or at least 0.5 kW and/or at most 2 kW or at most 1.5 kW.

It is moreover also possible to produce such a layer through the use of a SiZr alloy target or SiZr composite target in the sputtering process with addition of oxygen as reactive gas, wherein the composition ratios of the sputtering target optionally correspond to the composition of the layer to be produced in terms of the proportions of zirconium and silicon.

The further layers having a relatively low refractive index and the layers having a relatively high refractive index may also be applied analogously.

Depending on the composition of the layer to be produced a target may contain one or more of the elements selected from aluminum, silicon, boron, zirconium, titanium, nickel, chromium, yttrium, hafnium or carbon.

In addition to the aforementioned sputtering process coating may also employ further physical and chemical coating processes such as for example ion beam sputtering, vapor deposition or chemical vapor deposition (CVD).

If SiO₂ is provided as further layers having a relatively low refractive index and Si₃N₄ is provided as a layer having a relatively high refractive index it is advantageous to employ reactive sputtering since in this case both the silicon oxide of the low refractive index layers and the silicon nitride for the high refractive index layers can be produced with the same target. Switching to the different layer materials can be done simply by altering the process parameters, in particular the composition of the process gas.

In the following description referring to the drawings, similar or identical features are given the same reference numerals.

FIGS. 1A to 1D show schematic representations of sectional views of exemplary coated articles 100, wherein the coated articles 100 each comprise a substrate 101 and an AR coating 102. The AR coating 102 alternately comprises low refractive index layers 103, 103′, 103″ and high refractive index layers 104, 104′, 104″. The terminating layer 105 is part of the AR coating and is also a layer having a relatively low refractive index. At least one layer having a relatively low refractive index 103, 103′, 103″, 105 is a low refractive index Zr:SiOₓ-containing layer and it is preferable when at least the terminating layer 105 is a low refractive index Zr:SiOₓ-containing layer.

FIGS. 1A to 1D show four different variants of coated articles 100.

In the variants of FIGS. 1A and 1C the substrate 101 has a refractive index which is higher than the refractive index of the layers having a relatively low refractive index 103, 103′, 103″, 105 of the AR coating 102. The lowermost layer closest to the substrate is therefore composed of a layer having a relatively low refractive index. This lowermost layer having a relatively low refractive index 103 is alternately followed by respective layers having a relatively high refractive index 104, 104′, 104″ and layers having a relatively low refractive index 103′ and optionally 103″ until a five- or seven-layered AR coating is formed where the terminating layer 105 having a relatively low refractive index forms the uppermost layer.

In the variants of FIGS. 1B and 1D the substrate 101 has a refractive index which is the same as or lower than the refractive index of the layers having a relatively low refractive index 103, 103′, 103″, 105 of the AR coating 102. The lowermost layer closest to the substrate is therefore composed of a layer having a high refractive index 104. This lowermost layer having a high refractive index 104 is alternately followed by respective layers having a relatively low refractive index 103, 103′ and layers having a relatively high refractive index 104′ and optionally 104″ until a five- or seven-layered AR coating is formed where the terminating layer 105 having a relatively low refractive index forms the uppermost layer.

It may be preferable when at least the layer 105 and optionally also further layers having a relatively low refractive index 103, 103′ are low refractive index Zr:SiOₓ-containing layers, i.e. are composed of the composition X, wherein the composition X contains silicon oxide (SiO₂) and zirconium oxide (ZrO₂), wherein the proportion of zirconium in the metallic and semiconducting components in the composition X is from 0.2% to 10% by weight, optionally 0.2% to 5% by weight, optionally 0.5% to 3% by weight.

Such a low refractive index Zr:SiOₓ-containing layer and also the other layers of the AR coating may be applied for example by sputtering onto the surface of the substrate 101. This may be accomplished for example through co-sputtering of silicon and zirconium with addition of oxygen as reactive gas to produce the low refractive index Zr:SiOₓ-containing layer. It is moreover also possible to produce such a layer through the use of a SiZr alloy target in the sputtering process with addition of oxygen as reactive gas, wherein the composition ratios of the sputtering target optionally correspond to the composition of a layer to be produced.

As mentioned hereinabove the substrate 101 may be an optical glass, a filter glass or sapphire.

A terminating layer 105 which is in the form of a low refractive index Zr:SiOₓ-containing layer has very good mechanical properties in terms of avoiding scratches relative to a customary SiO₂-terminating layer which results from the doping of the layer composed substantially of SiO₂ with a defined proportion of ZrO₂. The effect of doping with ZrO₂ is elucidated below with reference to FIG. 2.

FIG. 2 shows the influence of the zirconium-to-silicon ratio on refractive index n and improvement of the mechanical properties (in %) in the case of an exemplary coated substrate having a low refractive index Zr:SiOₓ-containing layer as the terminating layer. The horizontal axis shows the ratio of zirconium to silicon in percent by weight based on the metal while the left-hand vertical axis shows the improvement in mechanical properties in percent. The bar graph shows the respective measured values for the improvement in mechanical properties. The two bars in each case describe measured values determined at different positions on the AR coating per data point. To determine the improvement in mechanical properties a test where sand was employed as the abrasive medium was used. The reported percentage describes the reduction in the scratched area of the coated substrate upon performing the scratch test compared to a customary terminating layer composed of SiO₂ (SiO₂ reference).

As is apparent in FIG. 2, all three inventive examples have an improved scratch resistance compared to the SiO₂ reference. However, an optimum of scratch resistance improvement is achieved at a proportion of about 3% by weight while at lower proportions, for example 2% by weight, or higher proportions, for example 4% by weight, the improvement in scratch resistance is smaller.

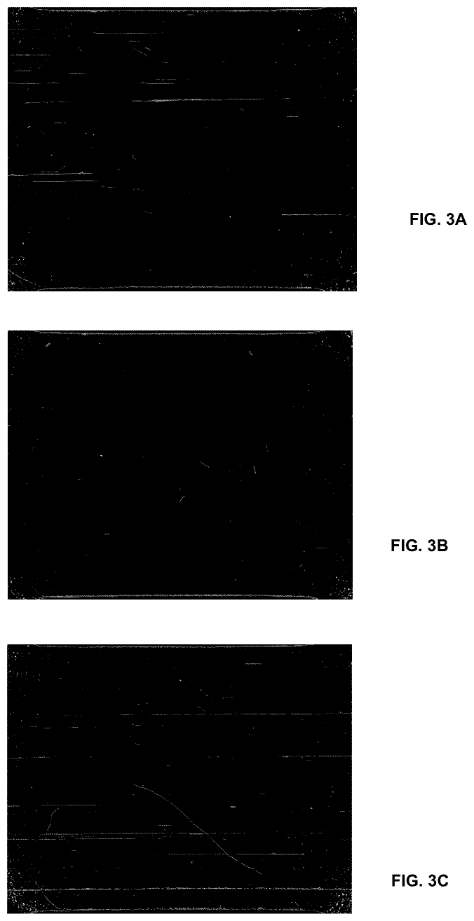

FIGS. 3A to 3C show exemplary detail views of an SiO₂ reference (FIG. 3A), an inventive coating according to example 3 (FIG. 3B) and a coating according to comp. ex. 2 (FIG. 3C) after performing an above-described scratch test. The coating of the substrate in FIG. 3B was an inventive terminating coating based on SiO₂ having a zirconium proportion of 3.0% by weight and a silicon proportion of 97.0% by weight at a thickness of the layer of 91 nm which was applied to one side of the substrate using a sputtering process. As is clearly apparent from a comparison of FIGS. 3A and 3B, the coating exhibits a markedly lower number of scratches than the SiO₂ reference of FIG. 3A, despite identical test conditions. A marked reduction in scratches which extend over only short distances is especially apparent. The AR coating according to comparative example 2 having a higher Zr content (FIG. 3C) exhibits a markedly higher number of scratches than the inventive example 2 (FIG. 3B).

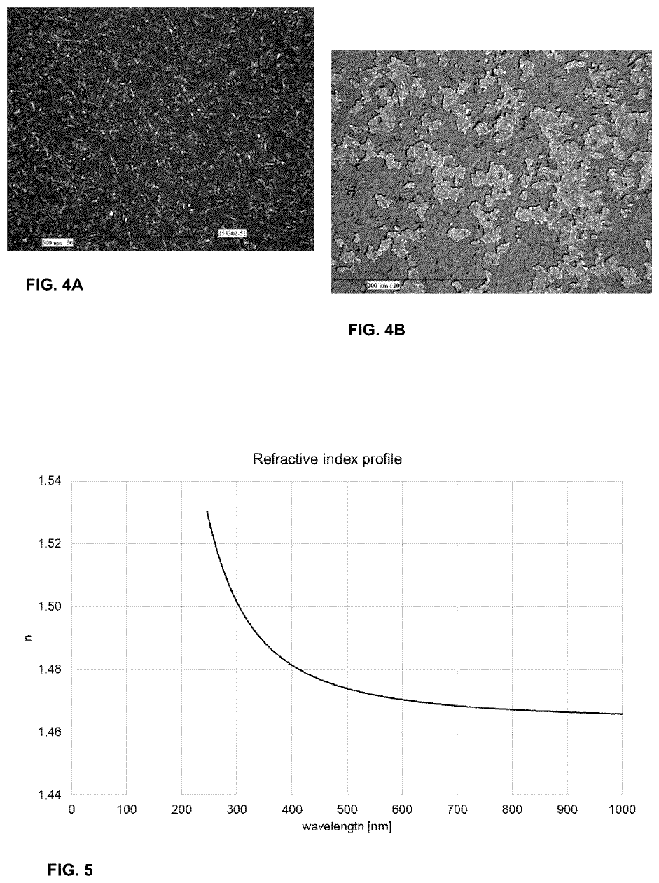

FIGS. 4A and 4B show detailed images of scratch tests for the SiO₂ reference (comp. ex. 1, FIG. 4B) and a Zr:SiOₓ coating according to inventive example 2 (FIG. 4A). It is apparent that in the case of the SiO₂ reference (FIG. 4B) large parts of the coating have become detached while in the case of the substrate coated according to the invention in FIG. 4A the coated surface suffered only a low level of damage which does not impair the antireflective effect of the AR coating.

The entire disclosures of all applications, patents and publications, cited above and below are hereby incorporated by reference.

The present invention will be illustrated below by a series of examples. However, the present invention is not limited to the examples mentioned.

### Examples

Table 1 shows the results of inventive AR coatings and comparative examples produced by co-sputtering of a silicon target and a zirconium target at different cathode powers, wherein the sputtering power on the silicon target was kept constant and the power on the Zr target was varied as shown in Table 1.

TABLE 1

| | | | | | | | Comp. | |
|---|---|---|---|---|---|---|---|---|
| | | | | | | | Ex. 1 | |
| | | | | | | | (SiO₂ | Comp. |
| | Ex. 1 | Ex. 2 | Ex. 3 | Ex. 4 | Ex. 5 | Ex. 6 | reference) | Ex. 2 |
| Substrate | | | | | | | | |
| Material | Sapphire | Sapphire | Sapphire | N-BK7 | Borofloat | Sapphire | Sapphire | Sapphire |
| AR coating | | | | | | | | |
| Layer 1 | SiO₂ | SiO₂ | SiO₂ | Si₃N₄ | Si₃N₄ | Zr:SiO₂ | SiO₂ | SiO₂ |
| material | | | | | | | | |
| Layer 2 | Si₃N₄ | Si₃N₄ | Si₃N₄ | SiO₂ | AlSiO₂ | Si₃N₄ | Si₃N₄ | Si₃N₄ |
| material | | | | | | | | |
| Layer 3 | SiO₂ | SiO₂ | SiO₂ | Si₃N₄ | Si₃N₄ | Zr:SiO₂ | SiO₂ | SiO₂ |
| material | | | | | | | | |
| Layer 4 | Si₃N₄ | Si₃N₄ | Si₃N₄ | — | AlSiO₂ | Si₃N₄ | Si₃N₄ | Si₃N₄ |
| material | | | | | | | | |
| Layer 5 | — | — | — | — | Si₃N₄ | Zr:SiO₂ | | |
| material | | | | | | | | |
| Layer 6 | — | — | — | — | — | Si₃N₄ | | |
| material | | | | | | | | |
| Terminating | | | | | | | | |
| layer | | | | | | | | |
| Material | Zr:SiO₂ | Zr:SiO₂ | Zr:SiO₂ | Zr:SiO₂ | Zr:SiO₂ | Zr:SiO₂ | SiO₂ | Zr:SiO₂ |
| Proportion of | 2.0 | 3.0 | 4.0 | 3.0 | 3.5 | 4.5 | — | 15 |
| Zr [wt %] | | | | | | | | |
| Sputtering | 0.5 | 0.75 | 1.0 | 0.75 | 0.8 | 1.0 | — | 3.0 |
| power [kW] | | | | | | | | |
| Layer | 91 | 91 | 91 | 100 | 80 | 90 | 91 | 91 |
| thickness | | | | | | | | |
| [nm] | | | | | | | | |

All inventive examples exhibited a markedly improved scratch resistance compared to the comparative examples.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

### LIST OF REFERENCE NUMERALS

100 Coated substrate
101 Substrate
102 Antireflective coating (AR coating)
103, 103′ Low refractive index layer
104, 104′, 104″ High refractive index layer
105 Terminating layer

What is claimed is:

1. A coated substrate, comprising:
a substrate; and
a multilayered antireflective coating built up from layers having different refractive indices on at least one side of the substrate, wherein layers having a relatively high refractive index and layers having a relatively low refractive index alternate and wherein at least one layer having a relatively low refractive index is composed of a composition X containing silicon oxide and zirconium oxide, wherein a proportion of zirconium in a metallic and semiconducting component in the composition X is 0.2% to 10% by weight.

2. The coated substrate of claim 1, wherein the proportion of zirconium in the metallic and semiconducting component in the composition X is 0.2% to 5% by weight.

3. The coated substrate of claim 1, wherein the at least one layer having a relatively low refractive index which is composed of the composition X containing silicon dioxide and zirconium oxide is an uppermost layer of the multilayered antireflective coating.

4. The coated substrate of claim 1, wherein the antireflective coating comprises at least two layers having a relatively high refractive index and at least two layers having a relatively low refractive index.

5. The coated substrate of claim 1, wherein the layers having a relatively low refractive index have a refractive index at a wavelength of 550 nm in a range from 1.3 to 1.6 and/or the layers having a relatively high refractive index have a refractive index at a wavelength of 550 nm in a range from 1.8 to 2.3.

6. The coated substrate of claim 1, wherein further layers having a relatively low refractive index contain SiO₂ or doped SiO₂ or Al-doped SiO₂.

7. The coated substrate of claim 1, wherein the layers having a relatively high refractive index are an oxide, silicide, carbide or nitride or mixed forms thereof of one or more metallic and semiconducting components selected from the group consisting of aluminum, silicon, boron, zirconium, titanium, nickel, tin, hafnium, chromium, and doped variants thereof.

8. The coated substrate of claim 1, wherein at least one layer having a relatively high refractive index is a transparent hard material layer containing crystalline aluminum nitride having a hexagonal crystal structure with a predominating (001) preferred direction.

9. The coated substrate of claim 1, wherein the antireflective coating has a total layer thickness in a range from 200 nm to 400 nm.

10. The coated substrate of claim 1, wherein the substrate has a curved surface coated with the antireflective coating.

11. The coated substrate of claim 1, wherein the substrate has a lenticular surface coated with the antireflective coating.

12. The coated substrate of claim 1, wherein the substrate is transparent.

13. The coated substrate of claim 1, wherein the substrate is a glass, an optical glass, a crystal for optical purposes, a plastic for optical purposes, or a glass ceramic.

14. The coated substrate of claim 1, wherein the substrate is a glass selected from the group consisting of sapphire glass, borosilicate glass, aluminosilicate glass, soda-lime glass, synthetic quartz glass, and lithium aluminosilicate glass.

15. The coated substrate of claim 1, wherein the substrate is a chemically or thermally toughened glass.

16. A process for producing a coated substrate, comprising:
applying a multilayered antireflective coating on at least one side of a substrate, wherein the antireflective coating is built up from layers having different refractive indices by successive deposition, wherein layers having a relatively high refractive index and layers having a relatively low refractive index alternate, wherein the layers having a relatively low refractive index are built up from silicon oxide comprising a proportion of aluminum and wherein at least one layer having a relatively low refractive index which is composed of a composition X containing silicon oxide and zirconium oxide is applied, wherein a proportion of zirconium in a metallic and semiconducting component in the composition X is 0.2% to 10% by weight.

17. A component, comprising:
a coated substrate comprising:
a substrate; and
a multilayered antireflective coating built up from layers having different refractive indices on at least one side of the substrate, wherein layers having a relatively high refractive index and layers having a relatively low refractive index alternate and wherein at least one layer having a relatively low refractive index is composed of a composition X containing silicon oxide and zirconium oxide, wherein a proportion of zirconium in a metallic and semiconducting component in the composition X is 0.2% to 10% by weight;
wherein the component is selected from the group consisting of: a watch glass; an optical component; a head-up display; an eyepiece for augmented reality; a cooking surface; a display for smartwatches, tablet PCs, or mobile telephones; and a touch display for smartwatches, tablet PCs, or mobile telephones.
